(19) United States
(12) Patent Application Publication
(10) Pub. No.: US 2024/0381716 A1
(43) Pub. Date: Nov. 14, 2024

(54) DISPLAY SUBSTRATE

(71) Applicants: HEFEI BOE JOINT TECHNOLOGY CO., LTD., Hefei (CN); BOE TECHNOLOGY GROUP CO., LTD., Beijing (CN)

(72) Inventors: Luke DING, Beijing (CN); Yongqian LI, Beijing (CN); Can YUAN, Beijing (CN)

(21) Appl. No.: 18/249,397

(22) PCT Filed: May 20, 2022
(86) PCT No.: PCT/CN2022/094081

§ 371 Date: Apr. 18, 2023

(51) Int. Cl. H10K 59/131

(52) U.S. Cl. CPC H10K 59/131

(57) ABSTRACT

The disclosure provides a display substrate, which has a display region and a peripheral region, and includes a base substrate, a plurality of sub-pixels, a first power signal line and a second power signal line at least partially located in the display region, a first power signal bus and a second power signal bus located in the peripheral region; the sub-pixels are located in the display region; the first power signal line and the second power signal line are electrically connected to the first power signal bus and the second power signal bus, respectively; the second power signal bus includes a first part disposed on a side of the first power signal bus close to the display region, and a second part disposed on a side of the first power signal bus away from the display region, so as to at least partially surround the first power signal bus.

### TECHNICAL FIELD

The embodiments of the present disclosure relate to a display substrate.

### BACKGROUND

In the display field, organic light emitting diode (OLED) display panel has the characteristics of self-illumination, high contrast, low energy consumption, wide viewing angle, fast response, capable of being used for flexible panel, wide usage temperature range, simple manufacturing process, and has broad development prospects.

### SUMMARY

At least one embodiment of the present disclosure provides a display substrate, the display substrate has a display region, and a peripheral region at least partially surrounding the display region, and includes a base substrate, a plurality of sub-pixels, a first power signal line, a second power signal line, a first power signal bus, and a second power signal bus. The plurality of sub-pixels are disposed on the base substrate and located in the display region, the first power signal line and the second power signal line are disposed on the base substrate and at least partially located in the display region, wherein the first power signal line is configured to transmit a first power signal to at least a portion of the plurality of sub-pixels, and the second power signal line is configured to transmit a second power signal different from the first power signal to at least a portion of the plurality of sub-pixels; the first power signal bus and the second power signal bus are disposed on the base substrate and located in the peripheral region, wherein the first power signal line is electrically connected to the first power signal bus, and the second power signal line is electrically connected to the second power signal bus, the second power signal bus includes a first part disposed on a side of the first power signal bus close to the display region, and a second part disposed on a side of the first power signal bus away from the display region, so as to at least partially surround the first power signal bus.

For example, the display substrate provided by at least one embodiment of the present disclosure further includes: a light-shielding layer, disposed on the base substrate, wherein each of the plurality of sub-pixels includes a light emitting device and a pixel driving circuit for driving the light emitting device, and the pixel driving circuit is disposed on a side of the light-shielding layer away from the base substrate, the first power signal bus is disposed at a same layer with the light-shielding layer.

For example, in the display substrate provided by at least one embodiment of the present disclosure, the pixel driving circuit includes a thin film transistor, the thin film transistor includes a gate electrode disposed on a side of the light-shielding layer away from the base substrate and a source/drain electrode located on a side of the gate electrode away from the base substrate, the first part and the source/drain electrode are disposed at a same layer.

For example, in the display substrate provided by at least one embodiment of the present disclosure, the second part and the gate electrode are disposed at a same layer.

For example, in the display substrate provided by at least one embodiment of the present disclosure, the second power signal bus further includes a third part and a fourth part that are electrically connected with the first part and the second part, and the third part and the fourth part are located on opposite two sides of the first power signal bus, the first part, the second part, the third part and the fourth part together surround the first power signal bus.

For example, in the display substrate provided by at least one embodiment of the present disclosure, the third part and the fourth part are disposed at a same layer with the first part and are integrally connected with the first part.

For example, in the display substrate provided by at least one embodiment of the present disclosure, a structure of the third part and a structure of the fourth part are symmetrical.

For example, the display substrate provided by at least one embodiment of the present disclosure further includes: a first power connection line, disposed at a same layer with the first power signal bus, and electrically connected to the first power signal bus and the first power signal line.

For example, in the display substrate provided by at least one embodiment of the present disclosure, the first power signal line is disposed at a same layer with the source/drain electrode, and is electrically connected to the first power connection line through a transition via hole.

For example, in the display substrate provided by at least one embodiment of the present disclosure, the second power signal line is disposed at a same layer with the source/drain electrode.

For example, in the display substrate provided by at least one embodiment of the present disclosure, the second power signal line extends from the display region to the peripheral region and is electrically connected to the first part.

For example, in the display substrate provided by at least one embodiment of the present disclosure, an electrical potential of the first power signal is higher than an electrical potential of the second power signal.

For example, the display substrate provided by at least one embodiment of the present disclosure further includes: a planarization layer and a first electrode layer; the planarization layer is disposed on a side of the source/drain electrode away from the base substrate, and includes a first via hole disposed in the peripheral region and exposing the first part and a second via hole disposed in the display region and exposing the source/drain electrode; the first electrode layer is disposed on a side of the planarization layer away from the base substrate, and includes a first electrode disposed in the display region and a connection electrode disposed in the peripheral region, wherein the first electrode is electrically connected to the source/drain electrode through the second via hole, and the connection electrode is electrically connected to the first part through the first via hole.

For example, the display substrate provided by at least one embodiment of the present disclosure further includes: a pixel definition layer, disposed on a side of the first electrode layer away from the base substrate, and includes a connection opening disposed in the peripheral region and a sub-pixel opening disposed in the display region, wherein the connection opening exposes the connection electrode, and the sub-pixel opening exposes the first electrode.

For example, the display substrate provided by at least one embodiment of the present disclosure further includes a light emitting material layer and a second electrode layer;

the light emitting material layer is at least partially disposed in the sub-pixel opening, the second electrode layer is disposed on a side of the light emitting material layer away from the base substrate, and extending from the display region to the peripheral region, and electrically connected to the connection electrode through the connection opening.

For example, in the display substrate provided by at least one embodiment of the present disclosure, the second electrode layer is terminated at a side of the first power signal bus close to the display region, and a gap is existed between the second electrode layer and the first power signal bus.

For example, in the display substrate provided by at least one embodiment of the present disclosure, the first part is at least partially overlapped with the first power connection line in a direction perpendicular to the base substrate, and the first part includes a first hollow part overlapped with the first power connection line in a direction perpendicular to the base substrate.

For example, in the display substrate provided by at least one embodiment of the present disclosure, the first part further includes a second hollow part that is not overlapped with the first power connection line in a direction perpendicular to the base substrate.

For example, in the display substrate provided by at least one embodiment of the present disclosure, at least one of the third part and the fourth part is at least partially overlapped with the first power connection line in a direction perpendicular to the base substrate, and at least one of the third part and the fourth part includes a third hollow part overlapped with the first power connection line in a direction perpendicular to the base substrate.

For example, in the display substrate provided by at least one embodiment of the present disclosure, the first power connection line includes a first trace part extending in a first direction and a second trace part extending in a second direction, and the first direction is different from the second direction, in a direction perpendicular to the base substrate, the first trace part is at least partially overlapped with the first part and is partially overlapped with the first hollow part, and the second trace part is overlapped with at least one of the third part and the fourth part, and is overlapped with the third hollow part.

### BRIEF DESCRIPTION OF THE DRAWINGS

In order to more clearly illustrate the technical schemes of the embodiments of the present disclosure, the accompanying drawings of the embodiments will be briefly described as below. It is obvious that the accompanying drawings in the following description are only related to some embodiments of the present disclosure, and thus are not intended to limit the present disclosure.

FIG. 1 is a pixel circuit view of a display substrate provided by at least one embodiment of the present disclosure;

FIG. 2A to FIG. 2C are signal timing diagrams of a driving method of a pixel circuit provided by at least one embodiment of the present disclosure;

FIG. 3 is a schematic plan view of a display substrate provided by at least one embodiment of the present disclosure;

FIG. 4 is a schematic plan view illustrating a portion of the display substrate in the dotted box region of FIG. 3;

FIG. 5 is an enlarged schematic plan view illustrating a portion of the display substrate in the dotted box region of FIG. 4;

FIG. 6 is a schematic partial sectional view illustrating a sub-pixel of a display substrate provided by at least one embodiment of the present disclosure; and

FIG. 7 to FIG. 13B are schematic partial plan views illustrating respective functional layers and schematic partial plan views of respective functional layers stacked in sequence of a display substrate provided by at least one embodiment of the present disclosure.

### DETAILED DESCRIPTION

In order to make objects, technical schemes and advantages of the embodiments of the disclosure apparent, the technical schemes of the embodiments will be described in a clearly and fully understandable way in connection with the drawings related to the embodiments of the disclosure. Apparently, the described embodiments are merely a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. As used in the present disclosure, “first,” “second,” and similar terms do not indicate any sequence, amount, or importance, but are merely used to distinguish various components. The terms “comprise,” “comprising,” “include,” “including,” etc., are intended to specify that the elements or the objects stated before these terms encompass the elements or the objects and equivalents thereof listed after these terms, but are not intended to exclude other elements or objects. The terms such as “connect” or “connected to each other” or the like are not limited to physical or mechanical connection, but can include electrical connection, whether direct or indirect. The terms “top,” “bottom,” “left” and “right” are only used to represent relative positional relationships, which may be correspondingly changed in the case that the absolute position of the described object is changed.

A display substrate usually includes a display region and a peripheral region surrounding the display region. The display region has a plurality of sub-pixels for display. At least some sub-pixels of the plurality of sub-pixels include a light emitting device and a pixel driving circuit for driving the light emitting device to emit light. The peripheral region includes a control circuit that provides control signals to the pixel driving circuit and a power bus and other structures.

With the development trend of large screen and narrow frame of display devices, the layout space of the above-mentioned control circuit and power bus and other structures in the peripheral region of the display substrate needs to be as small as possible. In this case, the circuit layout is too compact and prone to cause issues such as signal crosstalk. Therefore, how to reasonably use the limited layout space to arrange the above-mentioned circuit structure is an important direction to optimize the display substrate structure.

Among a plurality of sub-pixels of the display substrate, the pixel driving circuit is usually implemented as structures, such as 3T1C (three thin-film transistors and one storage capacitor), 7T1C (seven thin-film transistors and one storage capacitor), 8T1C (eight thin-film transistors and one storage capacitor) or 8T2C (eight thin-film transistors and two storage capacitors), so as to achieve the effect of driving the light emitting device. For example, the pixel driving circuit will be introduced as below taking 3T1C structure as an example, but the embodiments of the present disclosure do not limit the specific structure of the pixel driving circuit.

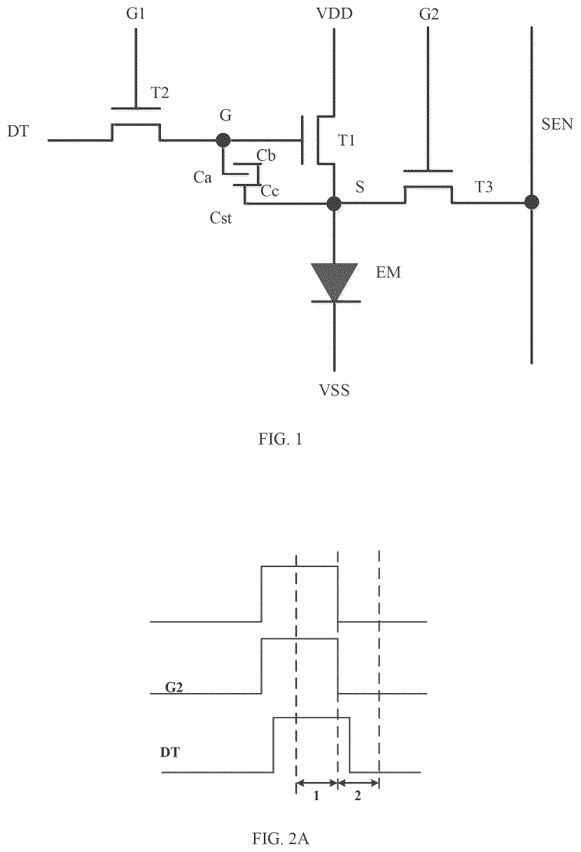

For example, the pixel driving circuit of the 3T1C structure includes a driving sub-circuit for driving the light emitting device to emit light and a detecting sub-circuit for detecting the electrical characteristics of the sub-pixel to achieve external compensation. For example, FIG. 1 is a schematic view of a 3T1C pixel driving circuit provided by at least one embodiment of the present disclosure.

Referring to FIG. 1, the pixel driving circuit includes a first transistor T1, a second transistor T2, a third transistor T3 and a storage capacitor Cst. The first transistor T1 is, for example, a driving transistor, and the second transistor T2 is, for example, a data writing transistor. A first source/drain electrode of the second transistor T2 is electrically connected to a first capacitor electrode Ca of the storage capacitor Cst and a gate electrode of the first transistor T1, a second source/drain electrode of the second transistor T2 is configured to receive a data signal DT, and the second transistor T2 is configured to write the data signal DT into the gate electrode of the first transistor T1 and the storage capacitor Cst in response to a first control signal G1; the first source/drain electrode of the first transistor T1 is electrically connected to a second capacitor electrode Cb of the storage capacitor Cst, and is configured to be electrically connected to a first electrode of a light emitting device EM, a second source/drain electrode of the first transistor T1 is configured to receive a first power voltage V1 (for example, receiving a high power voltage through a power signal line VDD), and the first transistor T1 is configured to control the current used to drive the light emitting device under the control of the voltage of the gate electrode of the first transistor T1; a first source/drain electrode of the third transistor T3 is electrically connected to the first source/drain electrode of the first transistor T1 and the second capacitor electrode Cb of the storage capacitor Cst, a second source/drain electrode of the third transistor T3 is configured to be connected to a sense line SEN, so as to be connected to an external sense circuit, and the third transistor T3 is configured to sense the electrical characteristics of the belonged sub-pixel in response to a second control signal G2, so as to achieve external compensation; the electrical characteristics include, for example, a threshold voltage and/or carrier mobility of the first transistor T1, or a threshold voltage and driving current of the light emitting device EM, etc. The external detection circuit is, for example, a conventional circuit including a digital-to-analog converter (DAC) and an analog-to-digital converter (ADC), which are not repeated by the embodiments of the present disclosure here.

For example, the storage capacitor Cst shown in FIG. 1 further includes a third capacitor electrode Cc, the third capacitor electrode Cc is located on a side of the first capacitor electrode Ca away from the second capacitor electrode Cb, and is electrically connected to the second capacitor electrode Cb to form a structure of parallel capacitor, so as to increase the capacitance value of the storage capacitor Cst. For example, the second electrode of the light emitting device EM is electrically connected to a power signal line VSS to receive low power voltage.

The transistors used in the embodiments of the present disclosure may be thin film transistors or other switching devices with the same characteristics. The source electrode and the drain electrode of the transistor used herein may be symmetrical in structure, therefore, there may be no difference between the structures of the source electrode and the drain electrode. In the embodiments of the present disclosure, in order to distinguish the two electrodes of the transistor other than the gate electrode, it is directly described that one electrode is the first source/drain electrode, and the other one electrode is the second source/drain electrode. In addition, transistors may be divided into N-type transistors and P-type transistors according to the characteristics of transistors. In the case that the transistor is a P-type transistor, a turn-on voltage is a low level voltage (for example, 0V, −5V,−10V or other appropriate voltage), and a turn-off voltage is a high level voltage (for example, 5V, 10V or other appropriate voltage); in the case that the transistor is a N-type transistor, a turn-on voltage is a high level voltage (for example, 5V, 10V or other appropriate voltage), and a turn-off voltage is a low level voltage (for example, 0V,−5V,−10V or other appropriate voltage). It should be noted that, in the following description, the transistor in FIG. 1 is an N-type transistor for example, but this description is not a limitation of the present disclosure.

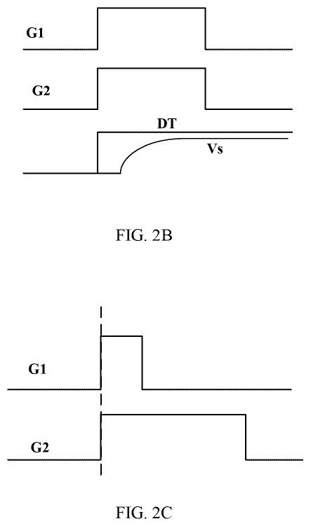

The working principle of the pixel driving circuit shown in FIG. 1 is described below in combination with the signal timing diagrams shown in FIG. 2A to FIG. 2C, wherein FIG. 2A illustrates a signal timing diagram of the pixel driving circuit in a display process, and FIG. 2B and FIG. 2C illustrate signal timing diagrams of the pixel driving circuit in a sensing process.

For example, as shown in FIG. 2A, the display process of each frame of image includes a data writing and reset stage 1 and a light emitting stage 2. FIG. 2A illustrates timing waveforms of respective signals in each stage. A working process of the 3T1C pixel driving circuit includes: in the data writing and reset stage 1, the first control signal G1 and the second control signal G2 are both turn-on signals, the second transistor T2 and the third transistor T3 are turned on, the data signal DT is transmitted to the gate electrode of the first transistor T1 through the second transistor T2, the first switch K1 is turned off, the analog-to-digital converter writes a reset signal to the first electrode (such as an anode) of the light emitting device EM through the sense line SEN and the third transistor T3, and the first transistor T1 is turned on and generates a driving current to charge the first electrode of the light emitting device to a working voltage; in the light emitting stage 2, the first control signal G1 and the second control signal G2 are both turn-off signals. Due to the bootstrap effect of the storage capacitor Cst, the voltage across the storage capacitor Cst remains unchanged, the first transistor T1 works in a saturated state and the current remains unchanged, and drives the light emitting device to emit light.

For example, FIG. 2B is a signal timing diagram of the pixel driving circuit while sensing the threshold voltage. A working process of the 3T1C pixel driving circuit includes: the first control signal G1 and the second control signal G2 are both turn-on signals, the second transistor T2 and the third transistor T3 are turned on, and the data signal DT is transmitted to the gate electrode of the first transistor T1 through the second transistor T2; the analog-to-digital converter writes a reset signal to the first electrode (node S) of the light emitting device EM through the sense line SEN and the third transistor T3, the first transistor T1 is turned on and charge the node S until the first transistor T1 is off, and the digital-to-analog converter samples the voltage on the sense line SEN to obtain the threshold voltage of the first transistor T1. This process may be performed, for example, while the display device is turned off.

For example, FIG. 2C illustrates a signal timing diagram of the pixel driving circuit while sensing the carrier mobility. A working process of the 3T1C pixel driving circuit includes: in a first stage, the first control signal G1 and the second control signal G2 are both turn-on signals, the second transistor T2 and the third transistor T3 are turned on, and the data signal DT is transmitted to the gate electrode of the first transistor T1 through the second transistor T2; the analog-to-digital converter writes a reset signal to the first electrode (node S) of the light emitting device EM through the sense line SEN and the third transistor T3; in a second stage, the first control signal G1 is a turn-off signal, the second control signal G1 is a turn-on signal, the second transistor T2 is turned off, the third transistor T3 is tuned on, and the sense line SEN is floating; due to the bootstrap effect of the storage capacitor Cst, the voltage across the storage capacitor Cst remains unchanged, the first transistor T1 works in a saturated state and the current remains unchanged and drives the light emitting device to emit light, then the digital-to-analog converter samples the voltage on the sense line SEN, and calculates the carrier mobility in the first transistor T1 by combining the magnitude and duration of the light emitting current. For example, this process may be performed in a blanking stage between display stages.

Through the above detection, the electrical characteristics of the first transistor T1 can be obtained and the corresponding compensation algorithm can be realized.

For example, the peripheral region of the display substrate includes a power bus that provides power signals for the power signal line VDD and the power signal line VSS respectively. Since the power signal line VDD is used to transmit a high-level signal, the high-level signal is prone to generate crosstalk with other signals transmitted on the display substrate, therefore, it is necessary to optimize the layout of the power bus.

At least one embodiment of the present disclosure provides a display substrate, which has a display region and a peripheral region at least partially surrounding the display region, and includes a base substrate, a plurality of sub-pixels, a first power signal line, a second power signal line, a first power signal bus and a second power signal bus; a plurality of sub-pixels are disposed on the base substrate and located in the display region, the first power signal line and the second power signal line are disposed on the base substrate and at least partially located in the display region, the first power signal line is configured to transmit a first power signal to at least a portion of the plurality of sub-pixels, and the second power signal line is configured to transmit a second power signal different from the first power signal to at least a portion of the plurality of sub-pixels; the first power signal bus and the second power signal bus are disposed on the base substrate and located in the peripheral region, the first power signal line is electrically connected to the first power signal bus, the second power signal line is electrically connected to the second power signal bus, and the second power signal bus includes a first part disposed on a side of the first power signal bus close to the display region and a second part disposed on a side of the first power signal bus away from the display region, so as to at least partially surround the first power signal bus.

In the above-described display substrate provided by the embodiments of the present disclosure, in the peripheral region, the second power signal bus at least partially surrounds the first power signal bus, thereby shielding the first power signal bus from electromagnetic interference, making the signal transmission of the first power signal bus more accurate, and improving the display effect of the display substrate.

The display substrate provided by the embodiments of the present disclosure is introduced in detail below through several specific embodiments.

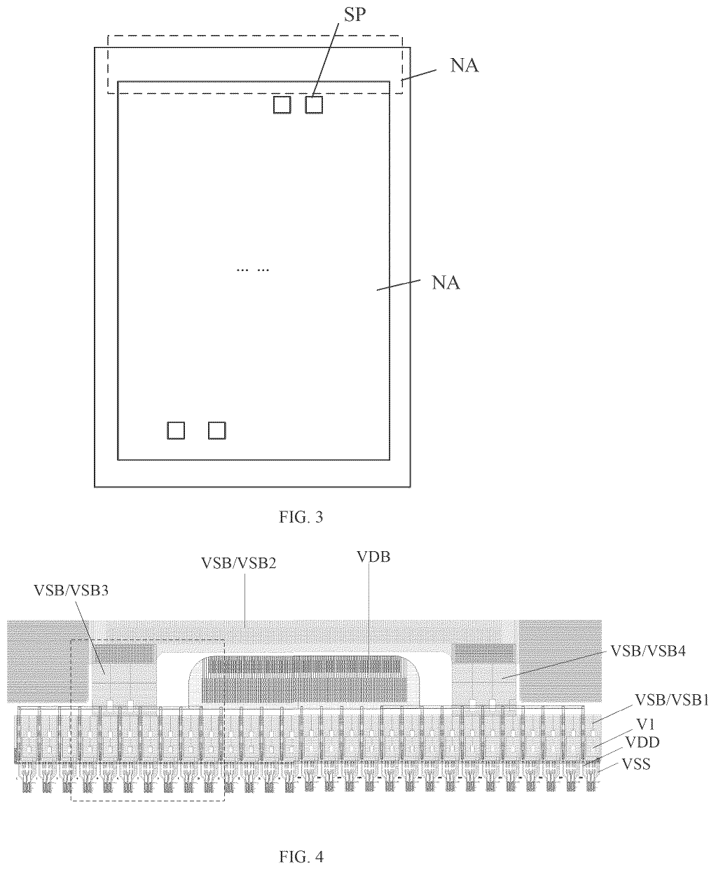

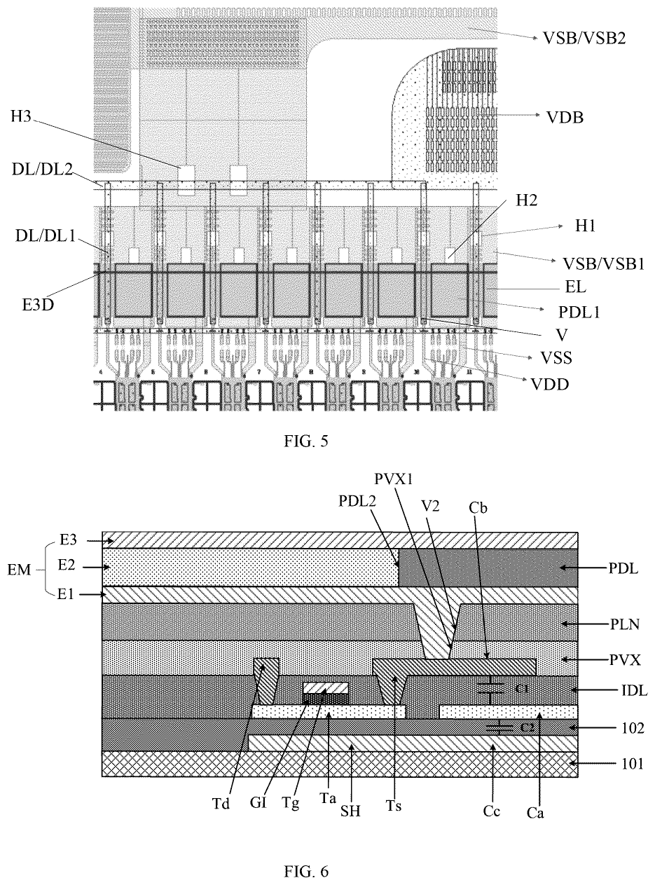

At least one embodiment of the present disclosure provides a display substrate. FIG. 3 illustrates a schematic plan view of the display substrate, FIG. 4 is an enlarged schematic view illustrating the display substrate in a dotted box region of FIG. 3, FIG. 5 is an enlarged schematic view illustrating the display substrate in a dotted box region of FIG. 4, and FIG. 6 is a partial schematic sectional view illustrating a sub-pixel of a display substrate.

As shown in FIG. 3, the display substrate has a display region AA and a peripheral region NA at least partially surrounding the display region AA. Referring to FIG. 3 to FIG. 6, the display substrate further includes a base substrate 101, a plurality of sub-pixels SP, a first power signal line VDD, a second power signal line VSS, a first power signal bus VDB, a second power signal bus VSB, and other structures.

The plurality of sub-pixels SP are disposed on the base substrate 101 and are located in the display region AA to realize the display effect. The first power signal line VDD and the second power signal line VSS are disposed on the base substrate 101 and at least partially located in the display region AA. The first power signal line VDD is configured to transmit first power signals to at least a portion of the plurality of sub-pixels SP, and the second power signal line VSS is configured to transmit second power signals different from the first power signals to at least a portion of the plurality of sub-pixels SP.

For example, in some embodiments, the electric potential of the first power signal is higher than the electric potential of the second power signal, that is, the first power signal line VDD is used to transmit a high power voltage, and the second power signal line VSS is used to transmit a low power voltage. For example, in some embodiments, the second power signal bus VSB may be grounded.

The first power signal bus VDB and the second power signal bus VSB are disposed on the base substrate 101 and located in the peripheral region NA. The first power signal line VDD is electrically connected to the first power signal bus VDB, so as to obtain the first power signal from the first power signal bus VDB. For example, in some embodiments, the first power signal line VDD may extend from the display region AA to the peripheral region NA to be electrically connected with the first power signal bus VDB. The second power signal line VSS is electrically connected to the second power signal bus VSB, so as to obtain the second power signal from the second power signal bus VSB. For example, in some embodiments, the second power signal line VSS may extend from the display region AA to the peripheral region NA to be electrically connected to the second power signal bus VSB.

For example, as shown in FIG. 4 and FIG. 5, the second power signal bus VSB includes a first part VSB1 disposed on a side (a lower side in the figure) of the first power signal bus VDB close to the display region AA and a second part VSB2 disposed on a side (an upper side in the figure) of the first power signal bus VDB away from the display region AA, so that the second power signal bus VSB at least partially surrounds the first power signal bus VDB. As such, the second power signal bus VSB can at least shield the first power signal bus VDB from electromagnetic interference on the opposite sides (upper and lower sides in the figure) of the first power signal bus VDB, such that the signal transmission of the first power signal bus VDB is more accurate and the display effect of the display substrate is improved.

For example, in some embodiments, as shown in FIG. 6, the display substrate further includes a light-shielding layer SH disposed on the base substrate 101. For example, each of the plurality of sub-pixels includes a light emitting device EM and a pixel driving circuit for driving the light emitting device. The pixel driving circuit is disposed on a side of the light-shielding layer SH away from the base substrate 101. For example, the pixel driving circuit includes a thin film transistor (driving transistor shown in FIG. 6) and a storage capacitor and other structures. The thin film transistor includes an active layer Ta disposed on a side of the light-shielding layer SH away from the base substrate 101, a gate electrode Tg disposed on a side of the active layer Ta away from the base substrate 101, and source/drain electrodes Td and Ts disposed on a side of the gate electrode Tg away from the base substrate 101. The source/drain electrodes Td and Ts are electrically connected to the active layer Ta through via holes respectively.

For example, in a direction perpendicular to the base substrate 101, that is, in the vertical direction in FIG. 6, the light-shielding layer SH is at least partially overlapped with the active layer Ta, so as to achieve the effect of shading the active layer Ta and avoid external light from shining on the active layer Ta and affecting the normal operation of the thin film transistor.

For example, as shown in FIG. 6, the storage capacitor includes a first capacitor electrode Ca, a second capacitor electrode Cb and a third capacitor electrode Cc. In the direction perpendicular to the base substrate 101, the first capacitor electrode Ca and the second capacitor electrode Cb are overlapped with each other to form a first capacitor C1, the first capacitor electrode Ca and the third capacitor electrode Cc are overlapped with each other to form a second capacitor C2, and the first capacitor C1 and the second capacitor C2 are connected in parallel. As such, the capacitance of the storage capacitor can be increased.

For example, as shown in FIG. 6, the first capacitor electrode Ca and the active layer Ta are disposed at the same layer, the second capacitor electrode Cb and the source/drain electrodes Td and Ts are disposed at the same layer, and the third capacitor electrode Cc and the light-shielding layer SH are disposed at the same layer, so as to simplify the fabrication process of the display substrate, and avoid the display substrate from having too many functional layers and increasing the thickness of the display substrate, thus facilitating the thin design of the display substrate.

It should be noted that, in the embodiments of the present disclosure, “disposed at the same” means that two or more functional layers or structural layers are formed at the same layer and formed of the same material in the hierarchical structure of the display substrate, that is, in the fabrication process, the two functional layers or structural layers may be formed from the same material layer, and may be formed by the same patterning process to form the required patterns and structures, thus the fabrication process of the display substrate can be simplified.

For example, in some embodiments, the first power signal bus VDB and the light-shielding layer SH are disposed at the same layer. For example, the first part VSB1 of the second power signal bus VSB and the source/drain electrodes Td and Ts are disposed at the same layer. For example, the second part VSB2 of the second power signal bus VSB and the gate electrode Tg are disposed at the same layer, which can further simplify the fabrication process of the display substrate and avoid the display substrate from having too many structural layers, such that the display substrate is thinned; in addition, the first power signal bus VDB, the first part VSB1 and the second part VSB2 of the second power signal bus VSB are made of different metal layers, respectively, which can increase the distance between the first power signal bus VDB and the second power signal bus VSB, so as to avoid short circuit and other undesirable phenomena caused by the signal lines being too close.

For example, in some embodiments, as shown in FIG. 4, the second power signal bus VSB further includes a third part VSB3 and a fourth part VSB4 electrically connected to the first part VSB1 and the second part VSB2. The third part VSB3 and the fourth part VSB4 are located on the opposite sides of the first power signal bus VDS, such as the left and right sides in FIG. 4. In this case, the first part VSB1, the second part VSB2, the third part VSB3 and the fourth part VSB4 together surround the first power signal bus VDB. For example, as shown in FIG. 4, the first part VSB1, the second part VSB2, the third part VSB3 and the fourth part VSB4 completely surround the first power signal bus VDB, so as to fully realize the function of preventing signal crosstalk for the first power signal bus VDB.

For example, in some embodiments, as shown in FIG. 4, the third part VSB3 and the fourth part VSB4 may be disposed at the same layer with the first part VSB1 and integrally connected with the first part VSB. The third part VSB3 and the fourth part VSB4 are electrically connected to the second part VSB2 through via holes, so that the first part VSB1, the second part VSB2, the third part VSB3 and the fourth part VSB4 of the second power signal bus VSB are formed as a whole, and used to transmit the same low power signal, which can reduce the voltage drop of the second power signal bus VSB.

For example, in some embodiments, as shown in FIG. 4, the structure of the third part VSB3 and the structure of the fourth part VSB4 are symmetrical, that is, they have basically the same shape, size, layout, etc., so that the signal transmission performance of the left and right sides of the display substrate can be basically consistent, and the display uniformity of the display substrate can be improved.

For example, in some embodiments, as shown in FIG. 5, the display substrate further includes a first power connection line DL, which may be disposed at the same layer with the first power signal bus VDB, that is, at the same layer with the light-shielding layer SH. The first power connection line DL is used to electrically connect the first power signal bus VDB to the first power signal line VDD.

For example, in some embodiments, the first power connection line DL may be disposed at the same layer with the first power signal bus VDB and integrally connected with the first power signal bus VDB.

For example, in some embodiments, as shown in FIG. 5, the first power signal line VDD may be disposed at the same layer with the source/drain electrodes Td and Ts, and is electrically connected to the first power connection line DL through the transition via hole V. For example, in some embodiments, the second power signal line VSS is disposed at the same layer with the source/drain electrodes Td and Ts, and is integrally connected with the first part VSB1 of the second power signal bus VSB.

For example, as shown in FIG. 5, the second power signal line VSS extends from the display region AA to the peripheral region NA and is electrically connected to, for example, integrally connected to the first part VSB1 of the second power signal bus VSB.

For example, in some embodiments, as shown in FIG. 5, in the direction perpendicular to the base substrate 101, the first part VSB1 of the second power signal bus VSB is at least partially overlapped with the first power connection line DL, and the first part VSB1 includes a first hollow part H1 that is overlapped with the first power connection line DL in the direction perpendicular to the base substrate 101, thereby reducing the overlapping area of the first power connection line DL and the first part VSB1, and avoiding the formation of structures such as parasitic capacitor between the first power connection line DL and the first part VSB1 that will affect the normal transmission of electrical signals.

For example, in some embodiments, as shown in FIG. 5, the first part VSB1 of the second power signal bus VSB further includes a second hollow part H2 that is not overlapped with the first power connection lines DL in the direction perpendicular to the base substrate 101. The setting of the second hollow part H2 can increase the area transparency, and reduce an etching difference in different regions of the first part VSB1 with a large area, and improve the etching uniformity of the first part VSB1 with a large area.

For example, in some embodiments, as shown in FIG. 4 and FIG. 5, in the direction perpendicular to the base substrate 101, at least one of the third part VSB3 and the fourth part VSB4 (such as both the third part VSB3 and the fourth part VSB4) of the second power signal bus VSB is at least partially overlapped with the first power connection line DL, and at least one of the third part VSB3 and the fourth part VSB4 (such as both the third part VSB3 and the fourth part VSB4) includes a third hollow part H3 that is overlapped with the first power connection line DL in the direction perpendicular to the base substrate 101, thereby reducing the overlapping area of the first power connection line DL with the third part VSB3 and the fourth part VSB4.

For example, in other embodiments, the third part VSB3 and the fourth part VSB4 may further include hollow parts (not shown in the figure) that are not overlapped with the first power connection line DL in the direction perpendicular to the base substrate 101, so as to improve the etching uniformity of the third part VSB3 and the fourth part VSB4.

For example, in some embodiments, as shown in FIG. 5, the first power connection line DL may include a first trace part DL1 extending along a first direction (vertical direction in the figure) and a second trace part DL2 extending along a second direction (horizontal direction in the figure). The first direction is different from the second direction, for example, the first direction is perpendicular to the second direction. For example, referring to FIG. 4 and FIG. 5, the first trace part DL1 includes a plurality of first traces that are parallel to each other; the second trace part DL2 includes two second traces that are disposed opposite to each other, and the two second traces are disposed on the same straight line. For example, a portion of the first traces is directly connected to the first power signal bus VDB, and a portion of the first traces is connected to the second trace, and electrically connected to the first power signal bus VDB through the second trace.

For example, in the direction perpendicular to the base substrate 101, the first trace part DL1 is at least partially overlapped with the first part VSB1 of the second power signal bus VSB and is overlapped with the first hollow part H1, and the second trace part DL2 is overlapped with at least one of the third part VSB3 and the fourth part VSB4 (for example, both the third part VSB3 and the fourth part VSB4) of the second power signal bus VSB, and is overlapped with the third hollow part H3.

For example, in some embodiments, as shown in FIG. 6, the display substrate further includes a planarization layer PLN and a first electrode layer. The planarization layer PLN is disposed on a side of the source/drain electrodes Td and Ts away from the base substrate 101 to planarize the pixel driving circuit and provide a flat surface, which facilitates disposing the first electrode layer. Referring to FIG. 4 and FIG. 6, the planarization layer PLN includes a first via hole V1 disposed in the peripheral region NA and exposing the first part VSB1 of the second power signal bus VSB, and a second via hole V2 disposed in the display region AA and exposing the source/drain electrode Ts.

For example, as shown in FIG. 6, the first electrode layer is disposed on a side of the planarization layer PLN away from the base substrate 101. Referring to FIG. 5 and FIG. 6, the first electrode layer includes a first electrode E1 disposed in the display region AA and a connection electrode EL disposed in the peripheral region NA. The first electrode E1 is electrically connected to the source/drain electrode Ts through the second via hole V2, and the connection electrode EL is electrically connected to the first part VSB1 of the second power signal bus VSB through the first via hole V1. For example, the first electrode E1 may be used as an anode of the light emitting device EM.

For example, in some embodiments, as shown in FIG. 6, the display substrate further includes a pixel definition layer PDL disposed on a side of the first electrode layer away from the base substrate 101. Referring to FIG. 5 and FIG. 6, the pixel definition layer PDL includes a connection opening PDL1 disposed in the peripheral region NA and a sub-pixel opening PDL2 disposed in the display region AA, the connection opening PDL1 exposes the connection electrode EL, and the sub-pixel opening PDL2 exposes the first electrode E1, thereby defining the effective light emitting region of the light emitting device EM.

For example, in some embodiments, as shown in FIG. 6, the display substrate further includes a light emitting material layer E2 and a second electrode layer E3. The light emitting material layer E2 is at least partially disposed in the sub-pixel opening PDL2, so that it can be driven to emit light by the first electrode E1 exposed by the sub-pixel opening PDL2. The second electrode layer E3 is disposed on a side of the light emitting material layer E2 away from the base substrate 101. For example, the second electrode layer E3 may be used as a cathode of the light emitting device EM. For example, in some embodiments, the second electrode layer E3 may be an electrode layer formed as a whole surface layer, that is, continuously disposed as being sheet shaped on the base substrate, and extending from the display region AA to the peripheral region NA, and the second electrode layer E3 is electrically connected to the connection electrode EL through the connection opening PLN1, so that the second electrode layer E3 can be electrically connected to the first part VSB1 of the second power signal bus VSB to receive low power signal.

For example, in some embodiments, as shown in FIG. 5, the second electrode layer E3 terminates at the side of the first power signal bus VDS close to the display region AA, for example, the termination boundary line of the second electrode layer E3 is E3D. Therefore, there has a gap between the second electrode layer E3 and the first power signal bus VDB, that is, there has a gap between the boundary line E3D and the first power signal bus VDB. For example, the gap distance is greater than 1.0 μm, such as 1.20 μm, 1.30 μm, 1.35 μm, 1.40 μm, 1.45 μm or 1.50 μm, etc. As such, the risk of short circuit between the second electrode layer E3 and the first power signal bus VDB can be reduced, and the fabrication yield of the display substrate can be improved.

For example, in some embodiments, the display substrate may further include structures such as a barrier layer and a buffer layer (not shown in the figure) that are disposed on the base substrate 101 to prevent impurities from entering into the respective functional layers on the base substrate 101 from the base substrate 101. For example, as shown in FIG. 6, the display substrate may further include structures such as an insulating layer 102 disposed on the light-shielding layer SH, a gate insulating layer GI disposed on the active layer Ta, an inter-layer insulating layer IDL disposed on the gate electrode Tg, a passivation layer PVX disposed on the source/drain electrodes Td and Ts, and an encapsulation layer disposed on the second electrode layer (not shown in the figure).

For example, the passivation layer PVX has a via hole PVX1 in spatial communication with the second via hole V2 of the planarization layer PLN, so that the first electrode E1 is electrically connected to the source/drain electrode Ts through the second via hole V2 and the via hole PVX1. For example, the passivation layer PVX further includes a via hole PVX2 in spatial communication with the first via hole V1 (see FIG. 11A, which will be described in detail later), so that the connection electrode EL is electrically connected to the first part VSB1 of the second power signal bus VSB through the first via hole V1 and the via hole PVX2.

For example, the encapsulation layer may be a composite encapsulation layer, which includes a stacked layer of a plurality of inorganic encapsulation layers and organic encapsulation layers, such as a three stacked layer structure of inorganic encapsulation layer/organic encapsulation layer/inorganic encapsulation layer, to have better encapsulation effect. For example, the display substrate may further include a structure, such as a cover plate (e.g., a glass transparent cover plate) or the like, disposed on the encapsulation layer. The embodiments of the present disclosure do not specifically limit other structures on the display substrate.

For example, in the embodiments of the present disclosure, the base substrate 101 may use a rigid substrate such as glass, quartz or the like, or a flexible substrate such as polyimide (PI), or the like. The materials of the active layer Ta and the first capacitor electrode Ca include but are not limited to silicon-based materials (amorphous silicon (a-Si), polycrystalline silicon (p-Si), etc.), metal oxide semiconductors (IGZO, ZnO, AZO, IZTO, etc.) and organic materials (hexathiophene, polythiophene, etc.). During the fabrication process, the semiconductor material of the first capacitor electrode Ca is converted to be a conductor to have good conductivity. The light-shielding layer SH, the third capacitor electrode Cc and the first power signal bus VDD may use metal materials or alloy materials, such as copper (Cu), aluminum (Al), molybdenum (Mo), magnesium (Mg), titanium (Ti), tungsten (W), or the like. For example, the gate electrode Tg and the second part VSB2 of the second power signal bus VSB may use metal materials or alloy materials, such as copper (Cu), aluminum (Al), molybdenum (Mo), magnesium (Mg), titanium (Ti), tungsten (W), or the like. For example, the gate electrode Tg and the second part VSB2 of the second power signal bus VSB may be single-layer structure or a multi-layer structure, such as a stacked layer structure of molybdenum titanium alloy and copper. For example, the source/drain electrodes Td and Ts, the second capacitor electrode Cb, and the first part VSB1, the third part VSB3 and the fourth part VSB4 of the second power signal bus VSB may use metal materials or alloy materials, such as copper (Cu), aluminum (Al), molybdenum (Mo), magnesium (Mg), titanium (Ti), tungsten (W), or the like, for example, which may also be formed into a single-layer structure or a multi-layer structure, such as a stacked layer structure of molybdenum titanium alloy and copper.

For example, the insulating layer 102, the gate insulating layer GI, the inter-layer insulating layer IDL, the passivation layer PVX and the inorganic encapsulation layer may be inorganic insulating layers, which are formed of inorganic insulating materials such as silicon oxide (SiOx), silicon nitride (SiNy) or silicon oxynitride (SiOxNy), or the like. For example, the planarization layer PLN, the pixel definition layer PDL and the organic encapsulation layer may be organic insulating layers, which may be formed of organic insulating materials such as polyimide (PI), acrylate, epoxy resin, polymethyl methacrylate (PMMA), or the like.

For example, the first electrode E1 and the connection electrode EL may use materials with high work function, such as transparent metal oxides, such as ITO, IZO, or the like. For example, the first electrode E1 may further include a metal layer such as Ag, so as to form a multi-layer structure of transparent metal oxide/metal layer. For example, the light emitting material layer E2 may include an organic light emitting material, so that the light emitting device EM is formed as an organic light emitting device (OLED); alternatively, in other embodiments, the light emitting material layer E2 may also include a quantum dot light emitting material, so that the light emitting device EM is formed as a quantum dot device (QLED). For example, the second electrode layer E3 may use a metal material or an alloy material, such as magnesium (Mg), lithium (Li), aluminum (Al), silver (Ag), or the like. The embodiments of the present disclosure do not limit the materials of the respective functional layer.

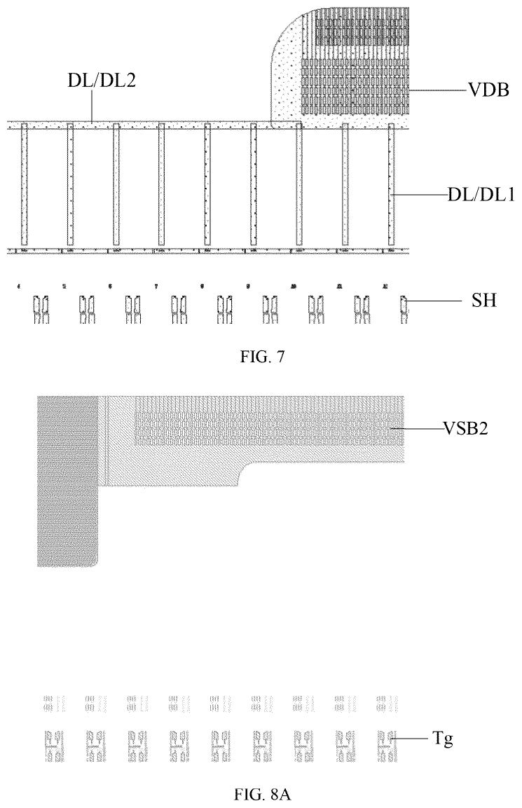

For example, FIG. 7 to FIG. 13B illustrate schematic partial plan views of the respective functional layers of the display substrate and schematic partial plan views of the respective functional layers stacked in sequence. Next, the respective functional layers of the display substrate and their relative position relationships are described below taking the structures in FIG. 7 to FIG. 13B as an example.

For example, FIG. 7 illustrates a partial plan view of a first conductive layer where the light-shielding layer SH is located. As shown in FIG. 7, the first conductive layer includes structures such as the light-shielding layer SH, the first power signal bus VDB, the first power signal connection line DL.

For example, in the fabrication process, the material of the first conductive layer may be formed on the base substrate 101 by a sputtering process, and the material of the first conductive layer may be patterned by a photolithography process, so as to obtain the patterns of the structures such as the light-shielding layer SH, the first power signal bus VDB, the first power signal connection line DL.

For example, the photolithography process may include processes such as coating, exposure, development, and etching. The details may refer to related technologies, which are not repeated here.

For example, referring to FIG. 6, the insulating layer 102 may be formed on the first conductive layer. During the fabrication process, the material of the insulating layer 102 may be formed by a deposition process. The material of the insulating layer 102 may include one or more selected from a group consisting of SiNx, SiOx and SiOxNy, and the thickness of the insulating layer 102 may be 150 nm to 500 nm, such as 200 nm, 300 nm or 400 nm.

For example, in the fabrication process, a semiconductor oxide (e.g., an amorphous oxide such as IGZO, ZnON, ITZO, etc.) may be formed on the insulating layer 102 by a sputtering process to form a semiconductor material layer, and the semiconductor material layer may be patterned by a photolithography process to form the patterns of the active layer Ta and the first capacitor electrode Ca. For example, the pattern of the first capacitor electrode Ca and the pattern of a portion of the active layer Ta may be subsequently processed to be conductive, for example, may be doped, to have good conductivity.

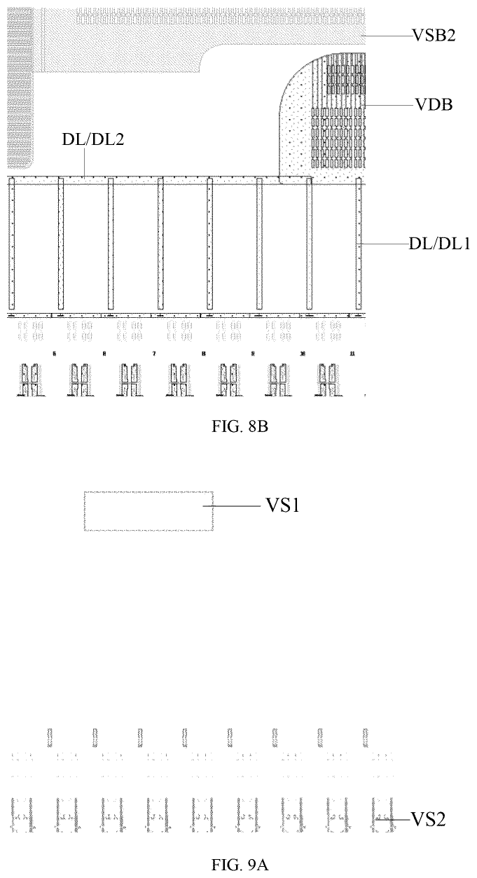

For example, in the fabrication process, the material of the gate insulating layer GI may be formed by a deposition process, and then a material of a second conductive layer may be formed on the material of the gate insulating layer GI by a sputtering process. The deposition thickness of the material of the second conductive layer may be 200 nm to 1000 nm, such as 400 nm, 600 nm or 800 nm, and the gate electrode Tg and the second part VSB2 of the second power signal bus VSB may be formed by a photolithography process, as shown in FIG. 8A. For example, the photoresist pattern used in the above photolithography process may not be stripped, the photoresist pattern may be used as a mask, and a dry etching process is used to etch the material of the gate insulating layer GI to form the pattern of the gate insulating layer GI, and the exposed semiconductor material layer is treated with gases such as NH³, N² or H², so as to be conductive, such that the treated semiconductor material layer has good conductivity.

For example, FIG. 8B is a schematic partial plan view illustrating the second conductive layer being stacked with the first conductive layer. As shown in FIG. 8B, the second part VSB2 of the second power signal bus VSB is located on a side of the first power signal bus VDB away from the display region AA.

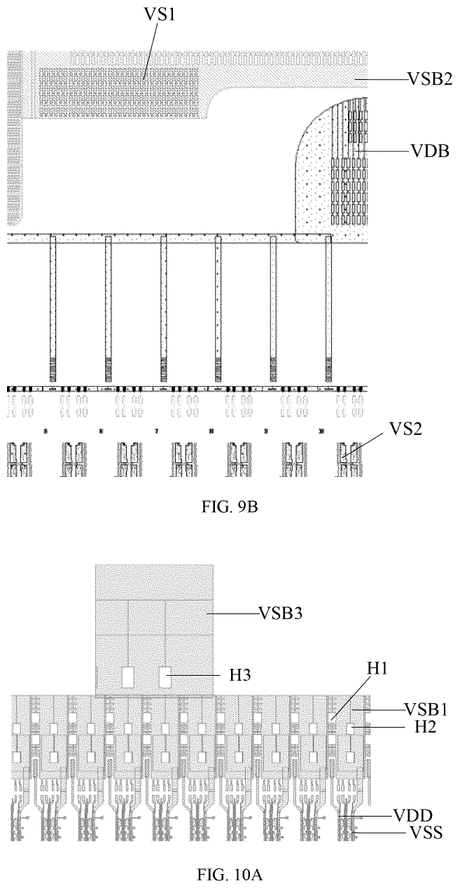

For example, FIG. 9A illustrates a schematic partial plan view of the inter-layer insulating layer IDL, as shown in FIG. 9A, the inter-layer insulating layer IDL includes the via hole VS1 used to electrically connect the third part VSB3 (and the fourth part VSB4) to the second part VSB2 of the second power signal bus VSB, and the via holes VS2 used to electrically connect the source/drain electrodes Ts/Td and the active layer Ta.

For example, in the fabrication process, the material of the inter-layer insulating layer IDL may be deposited on the second conductive layer by a deposition process, and the via holes VS1 and VS2 may be obtained by a dry etching process. For example, the material of the inter-layer insulating layer IDL may be a single-layer structure or a multi-layer structure formed of SiNx or SiOx.

For example, FIG. 9B is a schematic partial plan view illustrating the inter-layer insulating layer IDL being stacked with the second conductive layer and the first conductive layer. As shown in FIG. 9B, the via hole VS1 exposes the second part VSB2 of the second power signal bus VSB, and the via hole VS2 exposes the active layer Ta.

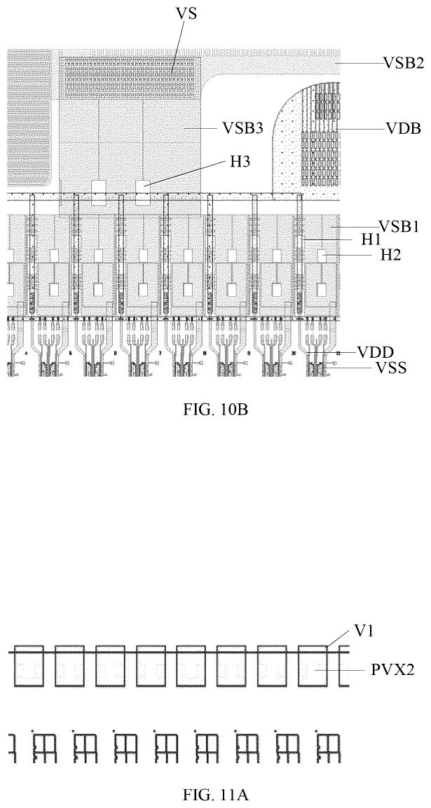

For example, during the fabrication process, a material of a third conductive layer may be formed on the inter-layer insulating layer IDL by a sputtering process. The deposition thickness of the material of the third conductive layer may be 200 nm to 1000 nm, and the source/drain electrodes Ts/Td, the first power signal line VDD, the second power signal line VSS, the first part VSB1, the third part VSB3 (and the fourth part VSB4) of the second power signal bus VSB may be formed by a photolithography process, as shown in FIG. 10A. For example, the first part VSB1 has the first hollow part H1 and the second hollow part H2, and the third part VSB3 (and the fourth part VSB4) has the third hollow part H3.

For example, FIG. 10B is a schematic partial plan view illustrating the third conductive layer being stacked with the inter-layer insulating layer IDL, the second conductive layer and the first conductive layer. As shown in FIG. 10B, the third part VSB3 (and the fourth part VSB4) of the second power signal bus VSB is electrically connected to the second part VSB2 through the via hole VS1, and the source/drain electrodes Ts/Td are electrically connected to the active layer Ta through the via holes VS2, which is not specifically shown in this figure, and may refer to FIG. 6.

For example, FIG. 11A is a schematic partial plan view illustrating the passivation layer PVX and the planarization layer PLN. During the fabrication process, the material of the passivation layer PVX, such as SiO₂, may be formed on the third conductive layer by a deposition process, and the pattern of the passivation layer PVX may be formed by a photolithography process. The passivation layer PVX includes the via hole PVX1 located in the display region AA and exposing the source/drain electrode Ts, and the via hole PXV2 located in the peripheral region NA and exposing the first part VSB1.

For example, a material of the planarization layer PLN (such as polyimide) may be formed on the passivation layer PVX by coating, and the water and organic solvent in the material may be removed by a post-baking at 230 degrees, so as to form the planarization layer PLN with a thickness of about 2.0 μm to 3.5 μM, thereafter, through exposure and development, the first via hole V1 located in the peripheral region NA and in spatial communication with the via hole PXV2 and the second via hole V2 located in the display region AA and in spatial communication with the via hole PVX1 are formed.

For example, FIG. 11B is a schematic partial plan view illustrating the passivation layer PVX and the planarization layer PLN being stacked with the third conductive layer, the inter-layer insulating layer IDL, the second conductive layer and the first conductive layer. As shown in FIG. 11B, in the peripheral region NA, the first via hole V1 and the via hole PXV2 expose the first part VSB1. In the display region AA, the second via hole V2 and the via hole PVX1 expose the source/drain electrode Ts, which is not shown in FIG. 11B and may refer to FIG. 6.

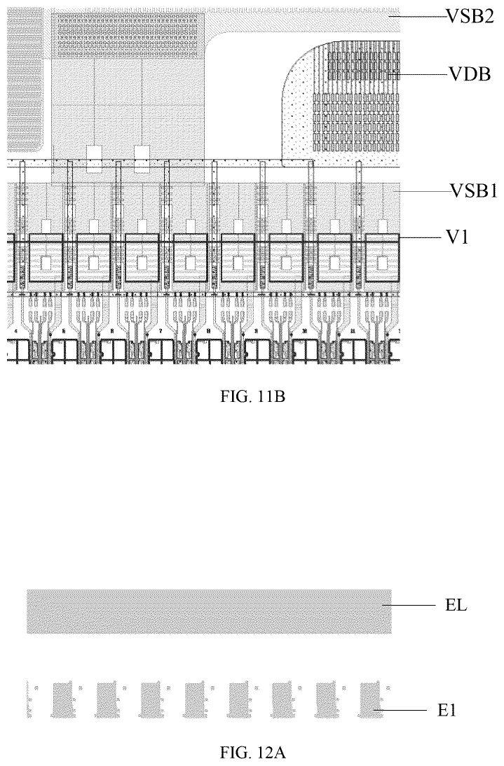

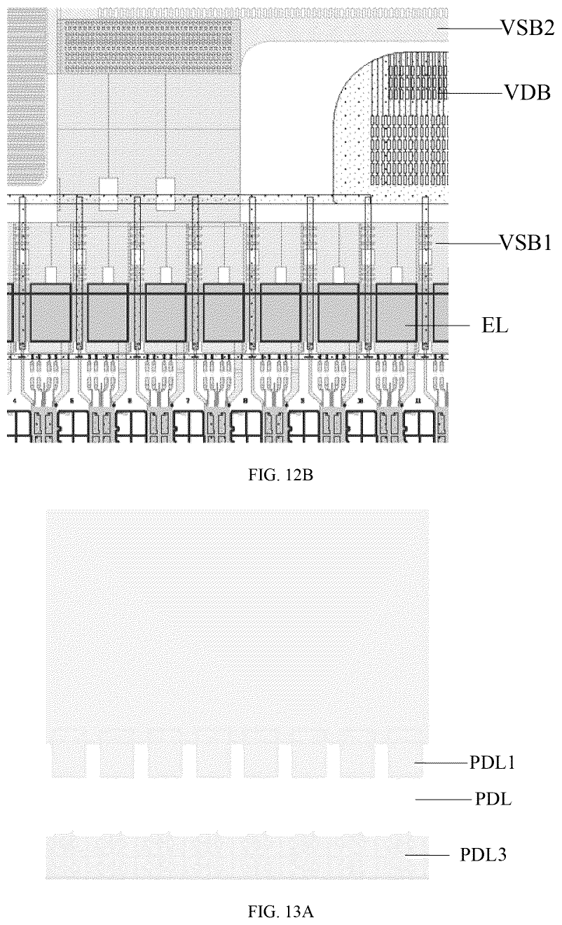

For example, FIG. 12A illustrates a partial plan view of the first electrode layer. As shown in FIG. 12A, the first electrode layer includes the first electrode E1 located in the display region AA and the connection electrode EL located in the peripheral region NA. During the fabrication process, the material of the first electrode layer may be formed on the planarization layer PLN by a sputtering process, and the thickness of the material is about 100 nm to 600 nm, such as 200 nm, 300 nm, 400 nm or 500 nm, or the like, and the patterns of the first electrode E1 and the connection electrode EL may be obtained by a photolithography process.

For example, FIG. 12B is a schematic partial plan view illustrating the first electrode layer being stacked with the passivation layer PVX, the planarization layer PLN, the third conductive layer, the inter-layer insulating layer IDL, the second conductive layer, and the first conductive layer. As shown in FIG. 12B, the connection electrode EL is electrically connected to the first part VSB1 through the via holes of the passivation layer PVX and the planarization layer PLN in the peripheral region NA. The first electrode E1 is electrically connected to the source/drain electrode Ts through the via holes of the passivation layer PVX and the planarization layer PLN in the display region AA, which is not specifically shown in FIG. 12B, and may refer to FIG. 6.

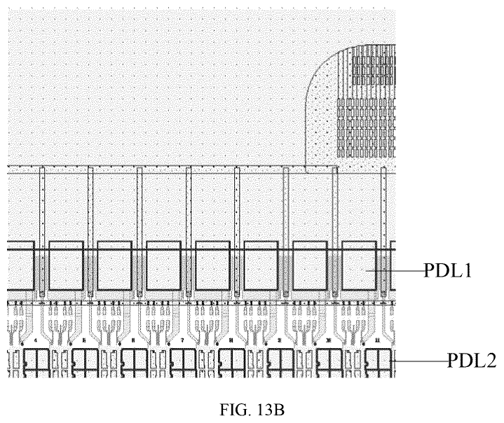

For example, FIG. 13A is a schematic partial plan view illustrating the pixel definition layer PLN. The shading part in the figure is the part where the material of the pixel definition layer PLN is removed. For example, the pixel definition layer PLN includes a sub-pixel opening region PDL3, and the sub-pixel opening region PDL3 has sub-pixel openings PDL2 for a plurality of sub-pixels, and the sub-pixel opening PDL2 exposes the first electrode E1, see FIG. 6. The pixel definition layer PLN further includes connection openings PDL1, which expose the connection electrode EL, so that the subsequently formed second electrode layer E3 is electrically connected to the connection electrode EL through the connection opening PDL1, and further electrically connected to the first part VSB1 of the second power signal bus VSB.

For example, in the fabrication process, the material of the pixel definition layer PLN may be formed by a coating process, and the pattern of the pixel definition layer PLN such as the connection openings PDL1, and the sub-pixel opening PDL2 may be formed by pre-baking, exposure, development, etc., and then the water and organic solvent in the pixel definition layer PLN may be removed by a post-baking at 230 degrees, and the pixel definition layer PLN with a thickness of 1.8 μm-2.0 μm is finally formed.

For example, FIG. 13B is a schematic partial plan view illustrating the pixel definition layer PLN being stacked with the first electrode layer, the passivation layer PVX, the planarization layer PLN, the third conductive layer, the inter-layer insulating layer IDL, the second conductive layer, and the first conductive layer. As shown in FIG. 13B, the connection opening PDL1 exposes the connection electrode EL, so that the subsequently formed second electrode layer E3 is electrically connected to the connection electrode EL through the connection opening PDL1.

For example, the display substrate further includes structures such as the light emitting material layer E2 (for example, formed by ink jet printing), the second electrode layer E3 (for example, formed by sputtering), the encapsulation layer, etc., whose forming method and specific structure may refer to relevant technologies and the description of FIG. 6, which are not repeated here.

In the embodiments of the present disclosure, both the second power signal line VSS and the first power signal line VDD in the display region AA are disposed at the same layer with the source/drain electrodes Ts and Td, and the first power signal line VDD is connected to the first power signal bus VDB through the via hole; the first power signal bus VDB is disposed at the same layer with the light-shielding layer SH, and different parts of the second power signal bus VSB are respectively disposed at the same layer with the gate electrode Tg and the source/drain electrodes Ts/Td, which can increase the distance between the high and low power signal lines. At the same time, the first power signal bus VDB is far away from the second electrode layer E3, which can prevent short circuit from being occurred between the first power signal bus VDB and the second electrode layer E3, and improve the yield of the display substrate; different parts of the second power signal bus VSB are respectively arranged on a side close to the display region AA and a side away from the display region AA to at least partially surround the first power signal bus VDB, which can provide electromagnetic shielding for the first power signal bus VDB; the second electrode layer E3 is electrically connected to the second power signal bus VSB through the connection opening in the pixel definition layer PDL and using the connection electrode EL that is disposed at the same layer with the first electrode E1, which is advantaged for the lap connection between the second electrode layer E3 and the second power signal bus VSB; in addition, the positions where the first power connection line DL electrically connected to the first power signal bus VDB is overlapped with the second power signal bus VSB adopt a grooved design, that is, the second power signal bus VSB has the first hollow part and the third hollow part, which can avoid the formation of parasitic capacitance; the second power signal bus VSB with a large area further has the second hollow part, which can increase the transparent area and reduce the etching difference, thereby ensuring the yield of the display substrate and improving the display effect.

In summary, the display substrate provided by the embodiments of the present disclosure can have better display effect and fabrication yield, while achieving narrow frame and large screen.

The following statements should be noted:
(1) The accompanying drawings only relate to the structures in connection with the embodiments of the present disclosure, and other structures can be referred to common designs.
(2) For clarity, in the accompanying drawings used to describe the embodiments of the present disclosure, the thickness of layers or regions is enlarged or reduced, that is, these drawings are not drawn to actual scale. It is understood that, in the case that an element such as a layer, a film, a region, or a substrate is referred to as located “above” or “below” another element, the element may be “directly” located “above” or “below” another element, or there may exist intermediate elements.
(3) In case of no conflict, features in one embodiment or in different embodiments can be combined to obtain new embodiments.

The above is only the specific embodiments of the disclosure, but the protection scope the disclosure is not limited thereto. The protection scope of the present disclosure should be subject to the protection scope of the claims.

1. A display substrate, having a display region, and a peripheral region at least partially surrounding the display region, and comprising:
a base substrate,
a plurality of sub-pixels, disposed on the base substrate and located in the display region,
a first power signal line and a second power signal line, disposed on the base substrate and at least partially located in the display region, wherein the first power signal line is configured to transmit a first power signal to at least a portion of the plurality of sub-pixels, and the second power signal line is configured to transmit a second power signal different from the first power signal to at least a portion of the plurality of sub-pixels;
a first power signal bus and a second power signal bus, disposed on the base substrate and located in the peripheral region, wherein the first power signal line is electrically connected to the first power signal bus, and the second power signal line is electrically connected to the second power signal bus,
the second power signal bus comprises a first part disposed on a side of the first power signal bus close to the display region, and a second part disposed on a side of the first power signal bus away from the display region, so as to at least partially surround the first power signal bus.

2. The display substrate according to claim 1, further comprising:
a light-shielding layer, disposed on the base substrate,
wherein each of the plurality of sub-pixels comprises a light emitting device and a pixel driving circuit for driving the light emitting device, and the pixel driving circuit is disposed on a side of the light-shielding layer away from the base substrate,
the first power signal bus is disposed at a same layer with the light-shielding layer.

3. The display substrate according to claim 2, wherein the pixel driving circuit comprises a thin film transistor, the thin film transistor comprises a gate electrode disposed on a side of the light-shielding layer away from the base substrate and a source/drain electrode located on a side of the gate electrode away from the base substrate,
the first part and the source/drain electrode are disposed at a same layer.

4. The display substrate according to claim 3, wherein the second part and the gate electrode are disposed at a same layer.

5. The display substrate according to claim 1, wherein the second power signal bus further comprises a third part and a fourth part that are electrically connected with the first part and the second part, and the third part and the fourth part are located on opposite two sides of the first power signal bus,
the first part, the second part, the third part and the fourth part together surround the first power signal bus.

6. The display substrate according to claim 5, wherein the third part and the fourth part are disposed at a same layer with the first part and are integrally connected with the first part.

7. The display substrate according to claim 5, wherein a structure of the third part and a structure of the fourth part are symmetrical.

8. The display substrate according to claim 3, further comprising:
a first power connection line, disposed at a same layer with the first power signal bus, and electrically connected to the first power signal bus and the first power signal line.

9. The display substrate according to claim 8, wherein the first power signal line is disposed at a same layer with the source/drain electrode, and is electrically connected to the first power connection line through a transition via hole.

10. The display substrate according to claim 3, wherein the second power signal line is disposed at a same layer with the source/drain electrode.

11. The display substrate according to claim 10, wherein the second power signal line extends from the display region to the peripheral region and is electrically connected to the first part.

12. The display substrate according to claim 1, wherein an electrical potential of the first power signal is higher than an electrical potential of the second power signal.

13. The display substrate according to claim 3, further comprising:
a planarization layer, disposed on a side of the source/drain electrode away from the base substrate, and comprises a first via hole disposed in the peripheral region and exposing the first part and a second via hole disposed in the display region and exposing the source/drain electrode,
a first electrode layer, disposed on a side of the planarization layer away from the base substrate, and comprises a first electrode disposed in the display region and a connection electrode disposed in the peripheral region, wherein the first electrode is electrically connected to the source/drain electrode through the second via hole, and the connection electrode is electrically connected to the first part through the first via hole.

14. The display substrate according to claim 13, further comprising:
a pixel definition layer, disposed on a side of the first electrode layer away from the base substrate, and comprises a connection opening disposed in the peripheral region and a sub-pixel opening disposed in the display region, wherein the connection opening exposes the connection electrode, and the sub-pixel opening exposes the first electrode.

15. The display substrate according to claim 14, further comprising:
a light emitting material layer, at least partially disposed in the sub-pixel opening,
a second electrode layer, disposed on a side of the light emitting material layer away from the base substrate, and extending from the display region to the peripheral region, and electrically connected to the connection electrode through the connection opening.

16. The display substrate according to claim 15, wherein the second electrode layer is terminated at a side of the first power signal bus close to the display region, and a gap is existed between the second electrode layer and the first power signal bus.

17. The display substrate according to claim 8, wherein the first part is at least partially overlapped with the first power connection line in a direction perpendicular to the base substrate, and the first part comprises a first hollow part overlapped with the first power connection line in a direction perpendicular to the base substrate.

18. The display substrate according to claim 17, wherein the first part further comprises a second hollow part that is not overlapped with the first power connection line in a direction perpendicular to the base substrate.

19. The display substrate according to claim 17, wherein at least one of the third part and the fourth part is at least partially overlapped with the first power connection line in a direction perpendicular to the base substrate, and at least one of the third part and the fourth part comprises a third hollow part overlapped with the first power connection line in a direction perpendicular to the base substrate.

20. The display substrate according to claim 19, wherein the first power connection line comprises a first trace part extending in a first direction and a second trace part extending in a second direction, and the first direction is different from the second direction,
in a direction perpendicular to the base substrate, the first trace part is at least partially overlapped with the first part and is partially overlapped with the first hollow part, and the second trace part is overlapped with at least one of the third part and the fourth part, and is overlapped with the third hollow part.
